(19) United States
(12) Patent Application Publication
(10) Pub. No.: US 2011/0007474 A1
(43) Pub. Date: Jan. 13, 2011

(54) COMBINED COMPUTER DEVICE AND FACILITY AIR PURIFICATION

(76) Inventors: Richard E. Detore, Clifton, VA (US); Stephen Petruzzo, Great Falls, VA (US)

Correspondence Address: DERGOSITS & NOAH LLP, Three Embarcadero Center, Suite 410, SAN FRANCISCO, CA, 94111, US

(21) Appl. No.: 12/827,062

(22) Filed: Jun. 30, 2010

Related U.S. Application Data
(60) Provisional application No. 61/223,502, filed on Jul. 7, 2009.

(51) Int. Cl. H05K 7/20

(52) U.S. Cl. 361/679.48

(57) ABSTRACT

High efficiency particulate air (HEPA) filter technology is utilized to purify facility air as well as the air utilized to cool a computer device, combining these functions into a single system to provide cost and energy savings.

### RELATED APPLICATION

This application claims the filing priority benefit of U.S. Provisional Application No. 61/223,502, titled “Air Cooled Computer Devices with Secondary Functionality of Air Purification” and filed on Jul. 7, 2009, by Richard E. Detore and Stephen Petruzzo. U.S. Provisional Application No. 61/223,502 is hereby incorporated by reference herein in its entirety.

### FIELD OF THE INVENTION

The present invention relates to filtered air flow computer device cooling systems and, more particularly, to the utilization of particulate air filter technology to purify facility air as well the air utilized to cool a computer device.

### DEFINITIONS

The term “computer device” as used in this document refers to any computer system that utilizes fan-based air cooling, including but not limited to desktop computers, workstation computers, multiple computers in a tower, chassis or racked configuration, and high density computer systems such as, for example, data centers that contain multiple racks of servers.

The term “high efficiency particulate air” or “HEPA” filter as used in this document refers to an air filtering system that removes at least 99.97% of airborne particles 0.3 micrometers (μm) in diameter.

### BACKGROUND OF THE INVENTION

### Computer Cooling

Computer cooling is the process of removing heat from the electrical components comprising a computer device. Because some of these computer device components produce large amounts of heat during operation, this heat must be dissipated in order to keep these components within safe operating temperature limits. Overheated electrical components experience a shorter useful life and exhibit sporadic problems that can cause computer device performance problems, including system freezes and crashes. Computer components that produce heat and are susceptible to performance loss and damage from overheating include, but are not limited to, central processing units (CPUs), graphics processing units (GPUs), chip sets, memory, graphics and other add-on cards, and hard disk drives.

While any method used to move air around a computer device can be considered to be a computer cooling technique, the utilization of fans is by far the most commonly utilized technique for accomplishing this task. The term “computer fan” usually refers to a fan that is attached to the computer device housing, but may encompass other types of computer fans as well, including, but not limited to, a chassis fan, a rack fan, a central processing unit (CPU) fan, a graphics processing unit (GPU) fan, a chip set fan, a power supply unit (PSU) fan, a hard disk drive (HDD) fan or a peripheral component interconnect (PCI) slot fan. The computer cooling fan need not necessarily be attached to the computer device housing, but may be spaced apart from the computer device housing to either draw cooling air to the housing or push cooling air through the housing. For example, one or more fans may be utilized to circulate cooling air around and or through the multiple computers that comprise a tower, chassis or racked computer device configuration.

The amount of heat build-up generated by the operation of an electrical component of a computer device is a function of the component design, the technology utilized in its construction and the frequency and voltage at which it operates. In the operation of the computer device, the temperature levels of the electrical components will rise until the temperature gradient between the computer components and their surroundings is such that the heat flow out of the computer device and the amount of heat generated by components reaches equilibrium. For reliable operation of the computer device, the equilibrium temperature must be sufficiently low for the computer device components to operate within their performance specifications.

The normal operation of computer device air cooling techniques can be hindered by a variety of causes, such as for example dust, sand, hair, fibers, dirt and smoke acting as a thermal insulator within the computer device and impeding air flow, thereby reducing heat sink and cooling fan performance. Prevention of these air cooling hindrances requires air filtration techniques.

As stated above, computer devices typically utilize one or more fans for heat management through air cooling. Most desktop computer power supplies have at least one fan associated with the power supply to exhaust air from the computer housing. Most manufacturers recommend bringing cool, fresh air in at the bottom front of the computer device housing and discharging warm air from the top rear of the housing. If there is more air being forced into the computer housing than is being pumped out, due to an imbalance in the number of fans, this is referred to as a “positive” airflow, since the pressure inside the computer housing is higher than the pressure outside the housing. A balanced or neutral air flow is the most efficient, although a slightly positive air flow results in less dust build up if dust filters are used.

### Indoor Air Quality

Indoor air quality is a major concern to businesses, building managers, tenants and employees because it can impact the health, comfort, well-being and productivity of facility occupants. Most Americans spend up to 90% of their time indoors, and many spend most of their working hours in an office environment. Studies conducted by the U.S. Environmental Protection Agency (EPA) and others show that indoor environments can sometimes have levels of pollutants that are actually higher than levels found outdoors.

Pollutants in an indoor environment can increase the risk of illness. Several studies by the EPA, states and independent scientific panels have consistently ranked indoor air pollution as an important environmental health problem. While most facilities do not have severe indoor air quality problems, even well-run facilities can sometimes experience episodes of poor indoor air quality. A 1989 EPA Report to Congress concluded that improved indoor air quality can result in higher worker productivity and fewer lost work days. The EPA estimates that poor indoor air quality may cost the nation tens of billions of dollars each year in lost worker productivity and medical care.

Indoor air quality can be aggravated by placement of computer devices within a facility by the movement of dust, dirt, hair, fibers, or other particles that would not normally be airborne. For example, placement of a computer device on the floor may agitate dust or carpet fiber particles into the air, which may then be inhaled by facility occupants.

Currently, controlling indoor air quality involves two main strategies. First, dilute pollutants and remove them from the building through filtered air. Second, use filtration to clean the air of pollutants. Solutions for improving indoor air quality include the utilization of high efficiency particulate air (HEPA) filters.

### HEPA Filters

A high efficiency particulate air, or HEPA, filter is a type of high-efficiency air filter. HEPA filters, according to the standard adopted by most industries, remove at least 99.97% of airborne particles 0.3 micrometers (μm) in diameter.

As is well known, HEPA filters are composed of a mat of randomly arranged fibers. The fibers are typically composed of fiberglass and possess diameters between about 0.5 and 2.0 microns. Key factors affecting function of a HEPA filter are fiber diameter, filter thickness and face velocity. The air space between HEPA filter fibers is much greater than 0.3 μm. The common assumption that a HEPA filter acts like a sieve where particle smaller than the largest opening can pass through is incorrect. Unlike membrane filters, where particles as wide as the largest opening or distance between fibers cannot pass in between them at all, HEPA filters are designed to target much smaller pollutants and particles. These particles are trapped (they stick to the fiber) through a combination of the following three mechanisms: (1) interception, where particles following a line of flow in the air stream come within one radius of a fiber and adhere to it; (2) impaction, where larger particles are unable to avoid fibers by following the curving contours of the air stream and are forced to embed in one of them directly (this effect increases with diminishing fiber separation and higher air flow velocity); and (3) diffusion, an enhancing mechanism that is the result of the collision with gas molecules by the smallest particles, especially those below 0.1 μm in diameter, which are thereby impeded and delayed in their path through the filter (this behavior is similar to Brownian motion and raises the probability that a particle will be stopped by either mechanism (1) or mechanism (2); it becomes dominant at lower air flow velocities). The diffusion mechanism predominates below the 0.1 μm diameter size. The impaction and interception mechanisms predominate above 0.4 μm. In between, near the 0.3 μm most penetrating particle size (MPPS), the diffusion and interception mechanisms predominate.

### Energy Considerations

Many homes, offices and other facilities operate both computer device cooling systems and separate air purification systems. This requires a capital expense for both systems and consumes energy for the operation of both systems.

Those skilled in the art will appreciate that it would be highly useful to have available a computer device cooling system that utilizes filter technology to not only cool a computer device but also purify the air in the facility in which the computer device is operating.

Those skilled in the art will also appreciate the energy and cost savings realized from operating a single system to accomplish both computer cooling and facility air purification functions.

### SUMMARY OF THE INVENTION

An embodiment of the invention provides an air purification system for a computer device. The air purification system comprises a fan (or fans) for moving air to the computer device and a high efficiency particulate air (HEPA) filter disposed such that air moving to the computer device passes through the HEPA filter.

Another embodiment of the invention provides a computer device system with air purification. The computer device system comprises: a computer device housing that houses electronic components, the computer device housing having an air intake opening and an air discharge opening; a fan (or fans) mounted within the computer device housing for causing air to pass though the computer device housing from the air intake opening to the air discharge opening; and a high efficiency particulate air (HEPA) filter disposed in proximity to the computer device housing such that air passing to the computer device housing passes through the HEPA filter.

Another embodiment of the invention provides an air purification method for a computer device. The air purification method comprises: utilizing a fan (or fans) to move air to the computer device and passing the air moving to the computer device through a high efficiency particulate air (HEPA) filter.

Another embodiment of the invention provides an air purification method for a computer device, the computer device being housed within a computer device housing having an air intake opening and an air discharge opening, and wherein a fan (or fans) is mounted within the computer device housing for causing air to pass through the computer device housing from the air intake opening to the air discharge opening. The air purification method comprises: causing air to pass through a high efficiency particulate air (HEPA) filter to provide filtered air and utilizing the fan to cause the filtered air to pass through the computer device housing from the air intake opening to the air discharge opening.

The features and advantages of the various aspects of the subject matter disclosed herein will be more fully understood and appreciated upon consideration of the following detailed description and the accompanying drawings, which set forth illustrative, non-limiting, embodiments in which the concepts of the claimed subject matter are utilized.

### DESCRIPTION OF THE DRAWINGS

FIG. 1 is a block diagram illustrating an embodiment of the invention.

FIG. 2 is a block diagram illustrating an alternate embodiment of the invention.

FIG. 3 is a block diagram illustrating a second alternate embodiment of the invention.

FIG. 4 is a block diagram illustrating a third alternate embodiment of the invention.

FIG. 5 is an exploded schematic perspective drawing illustrating an embodiment of a computer device utilizing a HEPA filter for air purification in accordance with the concepts of the present invention.

FIG. 6 is a schematic perspective drawing of an embodiment of a HEPA filter system utilizable in the FIG. 5 embodiment.

### DESCRIPTION OF THE INVENTION

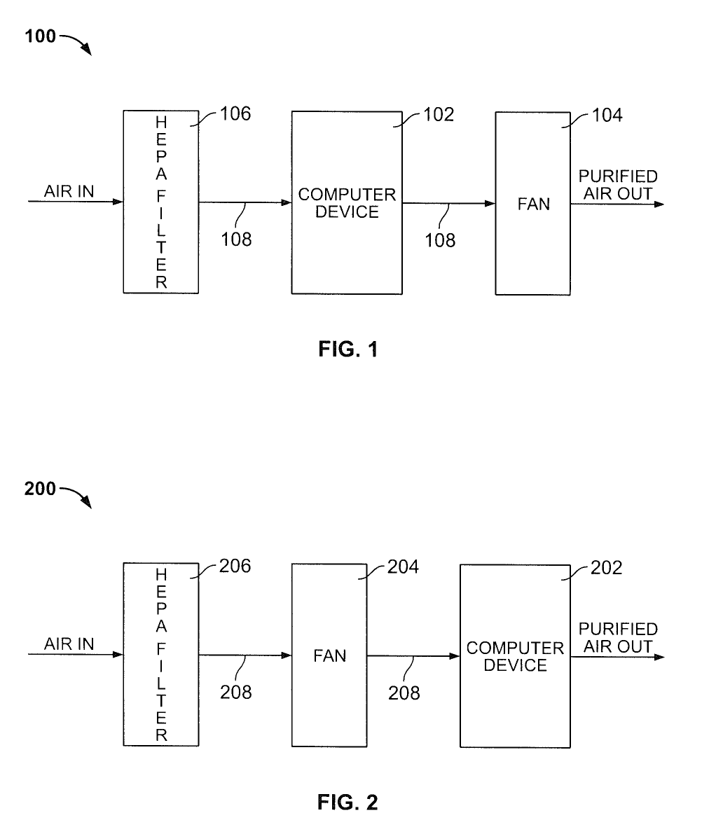

FIG. 1 shows an embodiment of an air purification system 100 for a computer device 102. The air purification system 100 includes a fan 104 that moves air (Air In) to the computer device 102. The air purification system 100 also includes a HEPA filter 106 that is disposed such that air moving to the computer device 102 passes through the HEPA filter 106. The fan 104 draws filtered air 108 that has passed through the HEPA filter 106 through the computer device 102 to cool electrical components (not shown) of the computer device 102. Cooling air 110 that has passed through the computer device 102 passes through the fan 104 as purified HEPA-filtered air (Purified Air Out) that enters the environment in which the computer device 102 is disposed.

FIG. 2 shows an embodiment of an air purification system 200 for a computer device 202. The air purification system 200 includes a fan 204 that moves air (Air In) to the computer device 202. The air purification system also includes a HEPA filter 206 that is disposed such that air moving to the computer device 202 passes through the HEPA filter 206. The fan 204 pushes filtered air 208 that has passed through the HEPA through the computer device 202 to cool electrical components (not shown) of the computer device 202. Cooling air that has passed through the computer device 202 enters the environment in which the computer device 202 is disposed as purified, HEPA-filtered air (Purified Air Out).

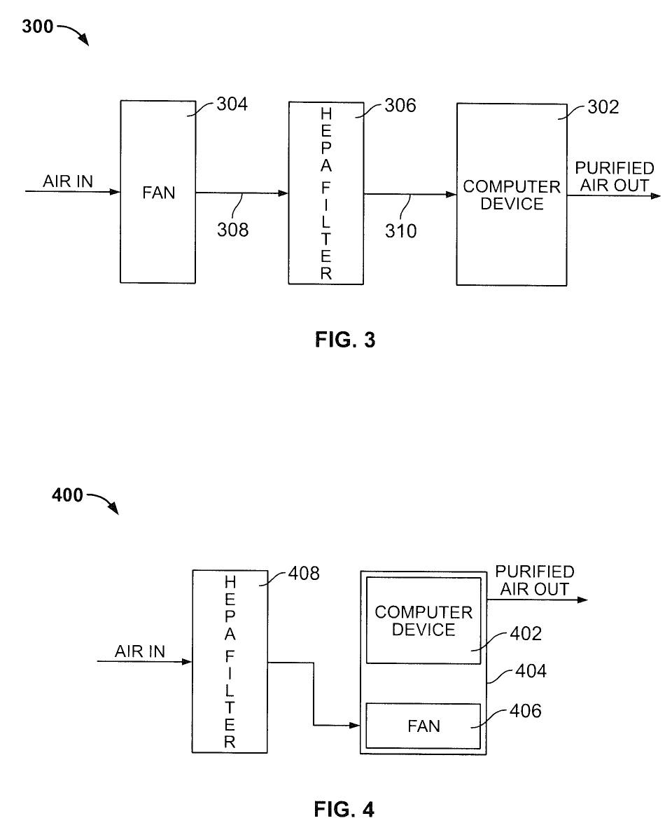

FIG. 3 shows an embodiment of an air purification system 300 for a computer device 302. The air purification system 200 includes a fan 304 that moves air (Air In) to the computer device 302 and to a HEPA filter 306. The HEPA filter is disposed such that air 308 provided by the fan 204 passes through the HEPA filter to provide filtered air 310 to the computer device 302. Cooling air that has passed through the computer device 302 enters the environment in which the computer device is disposed as purified, HEPA-filtered air (Purified Air Out).

FIG. 4 shows an air purification system 400 for a computer device 402 that is disposed within a computer device housing 404. The air purification system 400 includes a fan 406 disposed within the computer device housing 404 for moving air (Air In) to the computer device 402. The air purification system 400 also includes a HEPA filter 408 that is disposed such that air moving to the computer device 402 passes through the HEPA filter 408. The fan 406 moves filtered air 410 that has passed through the HEPA filter 408 through the computer device housing 404 to cool electrical components (not shown) of the computer device 402. Cooling air that has passed through the computer device housing 404 enters the environment in which the computer device housing 404 is disposed as purified, HEPA-filtered air (Purified Air Out).

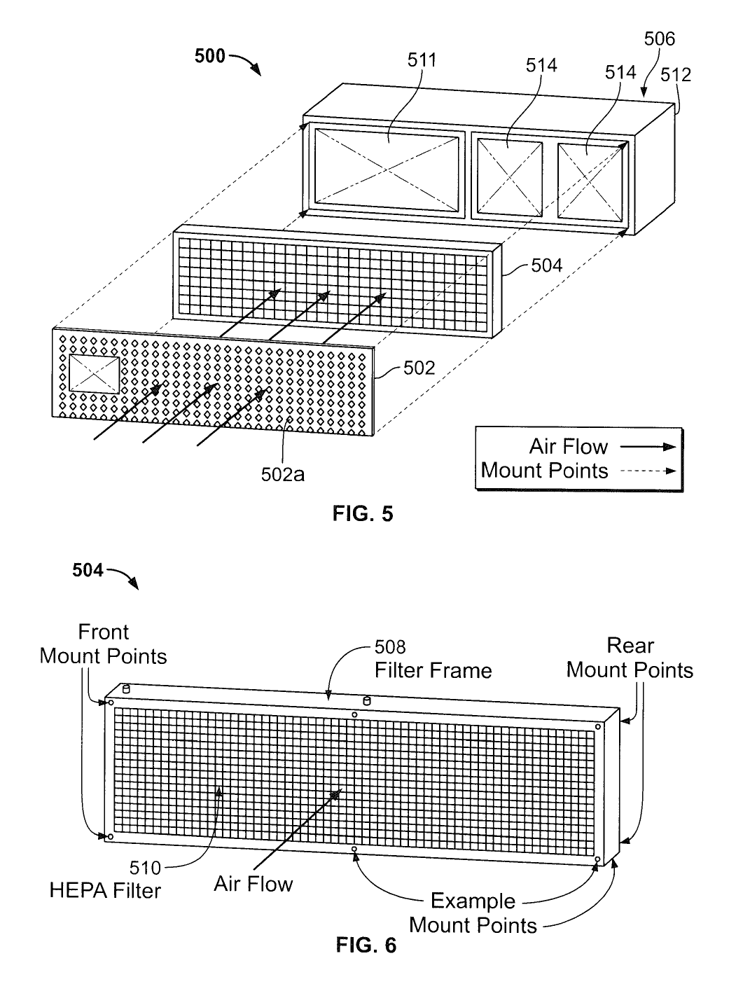

FIG. 5 shows an exploded view of an embodiment of a computer device system 500 with air purification. The illustrated computer device system includes an optional faceplate 502, an optional HEPA filter tray 504 and a computer device 506. The faceplate 502 includes a number of openings formed therein, shown as a grid of openings 502a in FIG. 5, to allow air to flow through the faceplate 502. As shown in FIG. 6, the HEPA filter tray 504 includes an optional filter frame 508 that holds a HEPA filter 510. In the FIG. 5 embodiment, the filter frame 508 includes mount points for attaching both the faceplate 502 and the HEPA filter tray 504 to the computer device 506. The solid arrows in FIG. 5 show the direction of air flow through the faceplate 502, the HEPA filter 510 and the computer device 506. The “dotted” arrows in FIG. 5 show example mount points for attaching the faceplate 502 and the HEPA filter tray 506.

As will be readily appreciated by those skilled in the art, the computer device 506 may include electronic components 511 mounted within a computer device housing 512 in the conventional manner. The computer device housing 512 may include air intake openings formed on one or both sides (i.e., in front of and/or behind the HEPA filter tray 504 and air discharge openings formed at its back side and/or top. One or more fans 514 are located within the computer device housing 512 to draw coolant air through the openings 502a in the faceplate 502, through the HEPA filter 510 and through the air intake openings of the computer device housing 512 to provide HEPA-filtered coolant air to the electronic components 511 of the computer device 506. The one or more fans 514 exhaust HEPA-filtered coolant air from the computer device housing 512 through the air discharge openings formed at the back side and/or top of the computer device housing 512.

Those skilled in the art will also readily appreciate that the electronic components 511 mounted within the computer device housing 512 of the computer device 506 may include a bulk power supply mounted along one side of the housing and cooled by HEPA-filtered coolant air through adjacent intakes. A plurality of input/output (I/O) or expansion cards may be located along the opposite side of the housing 512 and cooled by HEPA-filtered coolant air flowing through adjacent intakes. A plurality of system cards, including a processor card and memory cards, may be located within the housing 512 in parallel, rearwardly extending rows directly between air intake openings and the one or more fans. A DC/DC regulator card may be mounted in the housing over the system cards and may have a heat sink associated therewith that is provided with rearwardly extending cooling fins that are aligned in the direction of air flow from the air intake openings to the air discharge openings of the computer device housing.

As stated above, FIG. 6 shows a HEPA filter assembly 504 utilizable in the FIG. 5 computer device system. The FIG. 6 HEPA filter assembly 504 includes a HEPA filter (510) and a filter frame (508).

It should be understood that the particular embodiments of the invention described above have been provided by way of example and that other modifications may occur to those skilled in the art without departing from the scope and spirit of the invention as expressed in the appended claims and their equivalents.

What is claimed is:

1. An air purification system for a computer device, the system comprising:
a fan for moving air to the computer device; and
a high efficiency particulate air (HEPA) filter disposed such that air moving to the computer device passes through the HEPA filter.

2. The air purification system of claim 1, wherein the fan is disposed to draw air through the computer device.

3. The air purification system of claim 1, wherein the fan is disposed to push air through the computer device.

4. The air purification system of claim 1, and further comprising a computer housing that houses the computer device.

5. The air purification system of claim 4, wherein the fan is disposed within the computer housing.

6. The air purification system of claim 1, wherein the HEPA filter is disposed to be spaced apart from the computer device.

7. The air purification system of claim 1, wherein the system further comprises a computer device housing that houses the computer device and the HEPA filter is attached to the computer device housing.

8. The air purification system of claim 1, wherein the computer device comprises a desktop computer.

9. The air purification system of claim 1, wherein the computer device comprises multiple computers in a tower or racked configuration.

10. The air purification system of claim 1, wherein the computer device comprises a data center that contains multiple racks of servers.

11. A computer device system with air purification, the system comprising:
a computer device housing that a houses electronic components, the computer device housing having an air intake opening and an air discharge opening;
a fan mounted within the computer device housing for causing air to pass through the computer device housing from the air intake opening to the air discharge opening; and
a high efficiency particulate air (HEPA) filter disposed in proximity to the computer device housing such that air passing through the computer device housing passes through the HEPA filter.

12. The computer device system of claim 11, wherein the HEPA filter is spaced apart from the computer device housing.

13. The computer device system of claim 11, wherein the HEPA filter is attached to the computer device housing.

14. A method of air purification for a computer device, the method comprising:
utilizing a fan to move air to the computer device; and
passing the air moving to the computer device through a high efficiency particulate air (HEPA) filter.

15. A method of air purification for a computer device, the computer device being housed within a computer device housing having an air intake opening and an air discharge opening, and wherein a fan is mounted within the computer device housing for causing air to pass through the computer device housing from the air intake opening to the air discharge opening, the method comprising:
causing air to pass through a high efficiency particulate air (HEPA) filter to provide filtered air; and
utilizing the fan to cause the filtered air to pass through the computer device housing from the air intake opening to the air discharge opening.

16. The method of claim 15, wherein the HEPA filter is disposed to be spaced-apart from the computer device housing.

17. The method of claim 15, wherein the HEPA filter is attached to the computer device housing.

18. A method of air purification for a computer device system that includes a computer device housing that houses electronic components and a fan, the computer device housing having an air intake opening and an air discharge opening, the method comprising:
utilizing the fan to cause air to pass through the computer device housing from the air intake opening to the air discharge opening; and
passing air that passes through the computer device housing through a high efficiency particulate air (HEPA) filter.

19. The method of claim 18, wherein the HEPA filter is spaced apart from the computer device housing.

20. The method of claim 18, wherein the HEPA filter is attached to the computer device housing.
